(19) United States
(12) Patent Application Publication
(10) Pub. No.: US 2025/0046720 A1
(43) Pub. Date: Feb. 6, 2025

(54) SEMICONDUCTOR STRUCTURE HAVING CONDUCTIVE BRIDGE STRUCTURE

(71) Applicant: AP MEMORY TECHNOLOGY CORPORATION, HSINCHU COUNTY (TW)

(72) Inventors: WEN-LIANG CHEN, HSINCHU COUNTY (TW); CHUNG-CHIANG HUANG, HSINCHU (TW); YING-CHUN LIN, HSINCHU (TW); YEN-JUN LI, HSINCHU (TW)

(21) Appl. No.: 18/363,664

(22) Filed: Aug. 1, 2023

(51) Int. Cl. H01L 23/538; H01L 23/10; H01L 27/06

(52) U.S. Cl. CPC H01L 23/5381; H01L 23/10; H01L 27/0629

(57) ABSTRACT

A semiconductor structure is provided. The semiconductor structure includes a substrate, a device layer, and a metallization structure. The substrate has a first surface. The device layer is over the first surface of the substrate. The device layer includes a plurality of passive component units. The metallization structure is over the device layer. The metallization structure includes a conductive bridge portion electrically connecting two adjacent passive component units.

### FIELD

The present disclosure relates to a semiconductor structure, particularly, the semiconductor structure includes a conductive bridge structure that electrically connects two adjacent passive component units to electrically splice the two adjacent passive component units.

### BACKGROUND

Integrated circuit (IC) manufacturers are employing increasingly smaller dimensions and corresponding technologies to make smaller, high-speed semiconductor devices. Along with these advancements, the challenges of maintaining yield and throughput have also increased.

A semiconductor wafer typically includes die regions separated from each other by scribe lines. The scribing operation is carried out on the active side of the semiconductor wafers where the integrated circuits and the multi-layer wiring layers of the IC devices are formed, and the scribe lines are defined in the areas of the semiconductor wafer between each individual IC devices (e.g., die regions). Generally speaking, the areas of the scribe lines are designed to be free of any functional electrical wiring structure so as to prevent open circuit after dicing operations.

### BRIEF DESCRIPTION OF THE DRA WINGS

Aspects of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

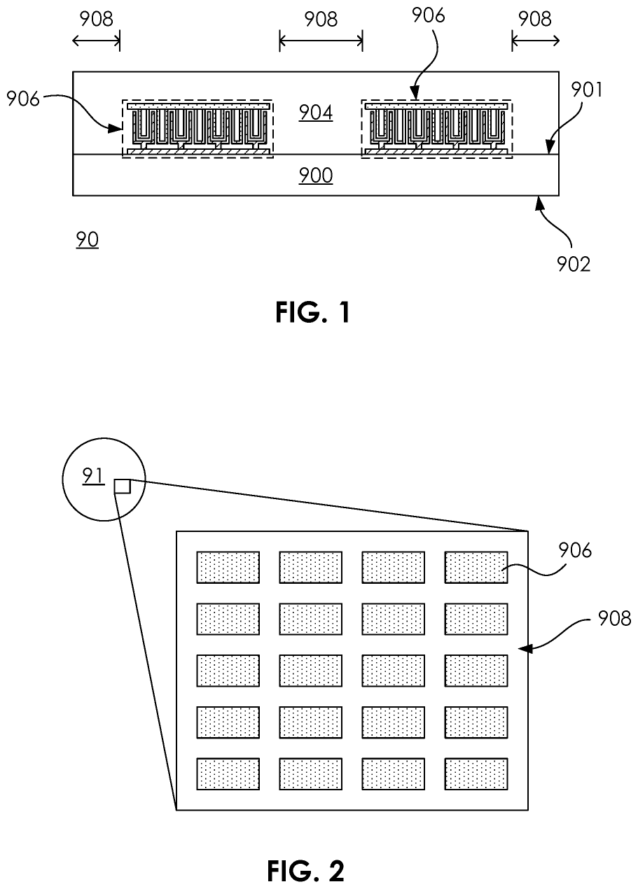

FIG. 1 illustrates a cross-sectional view of a semiconductor structure according to some comparative embodiments of the present disclosure.

FIG. 2 illustrates a top view of a portion of a semiconductor wafer according to some comparative embodiments of the present disclosure.

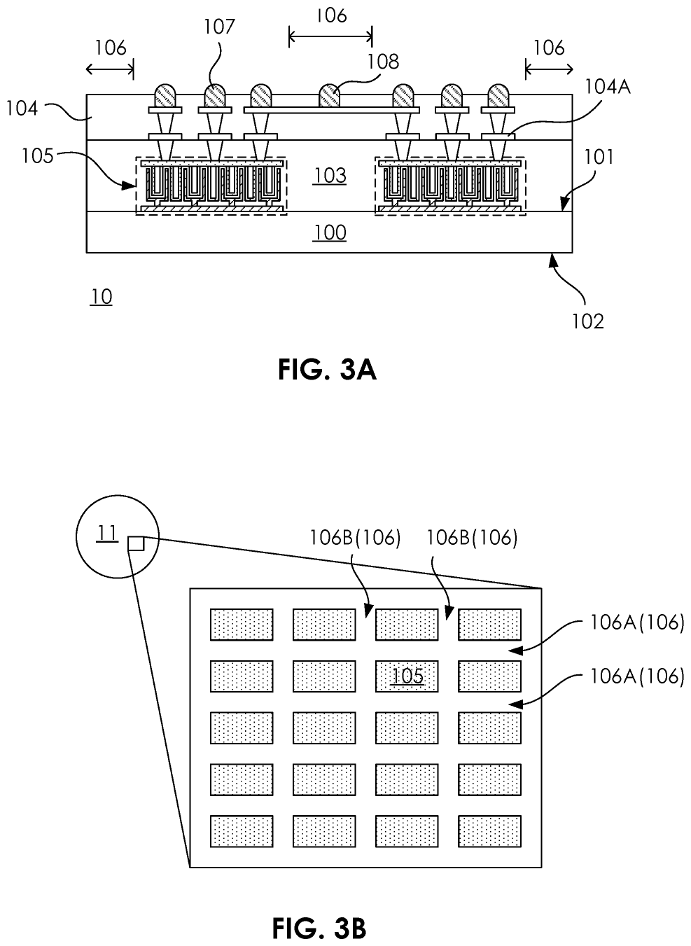

FIG. 3A illustrates a cross-sectional view of a semiconductor wafer according to some embodiments of the present disclosure.

FIG. 3B illustrates a top view of a portion of a semiconductor wafer according to some embodiments of the present disclosure.

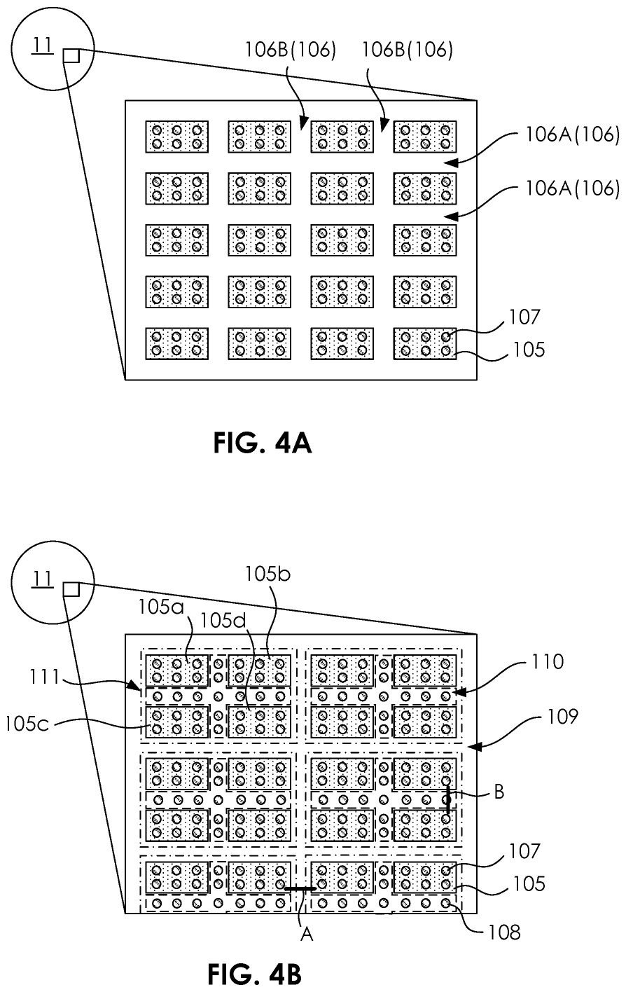

FIG. 4A illustrates a top view of a portion of a semiconductor wafer according to some comparative embodiments of the present disclosure.

FIG. 4B illustrates a top view of a portion of a semiconductor wafer according to some embodiments of the present disclosure.

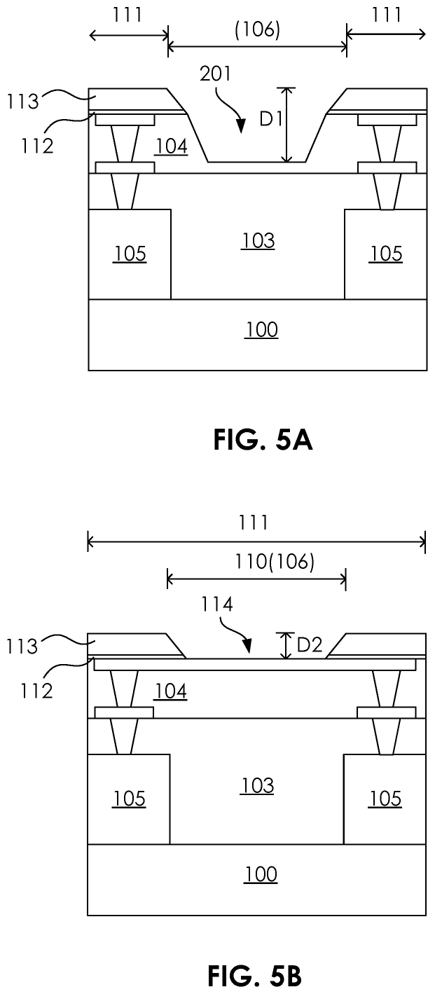

FIG. 5A illustrates a cross-sectional view of a semiconductor structure according to some embodiments of the present disclosure.

FIG. 5B illustrates a cross-sectional view of a semiconductor structure according to some embodiments of the present disclosure.

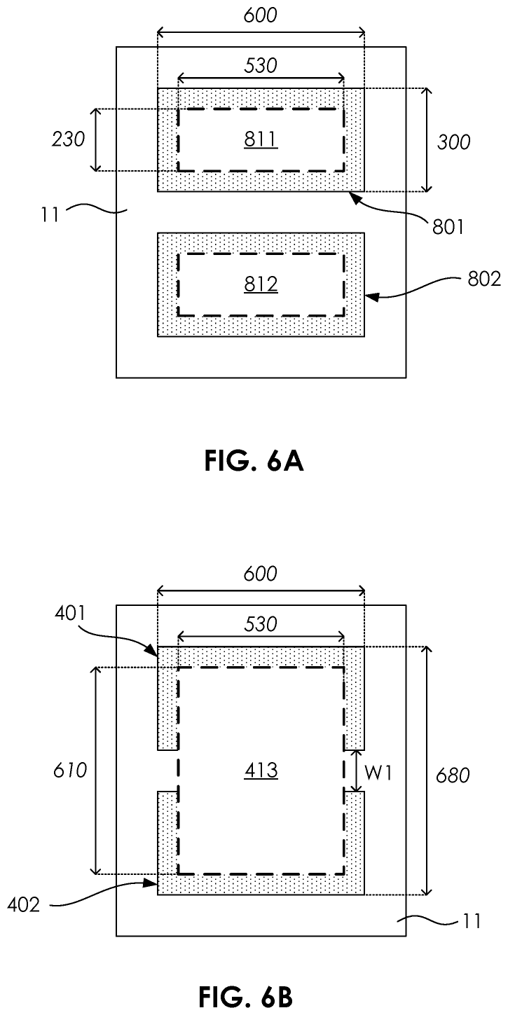

FIG. 6A illustrates a top view of a portion of a semiconductor wafer according to some comparative embodiments of the present disclosure.

FIG. 6B illustrates a top view of a portion of a semiconductor wafer according to some embodiments of the present disclosure.

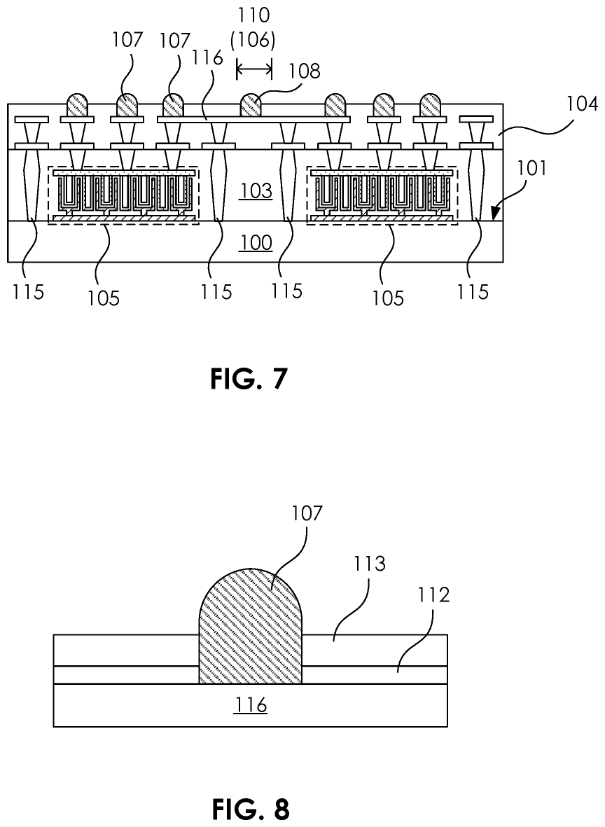

FIG. 7 illustrates a cross-sectional view of a semiconductor structure according to some embodiments of the present disclosure.

FIG. 8 illustrates a cross-sectional view of a semiconductor structure according to some embodiments of the present disclosure.

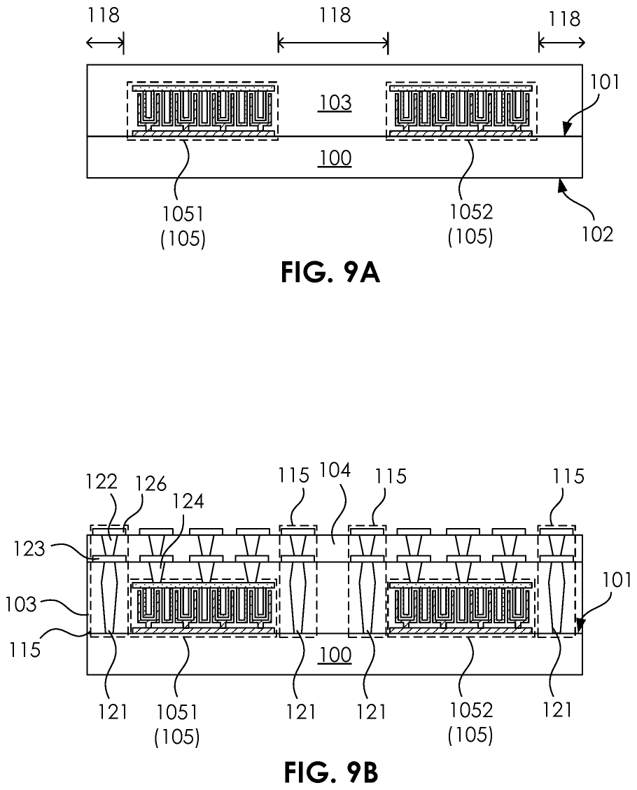

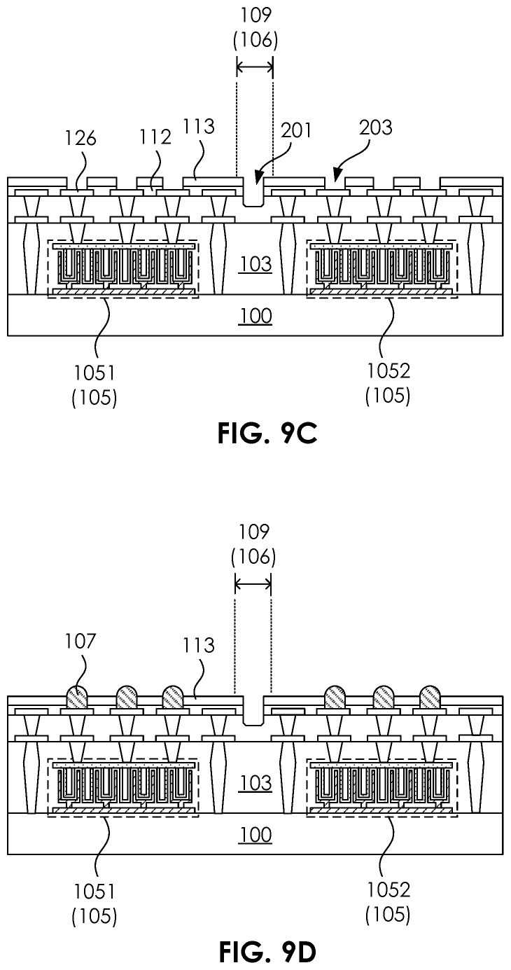

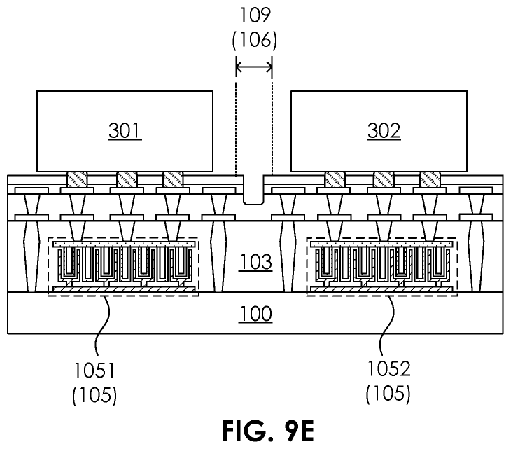

FIGS. 9A to 9E illustrate cross-sectional views of forming a semiconductor structure according to some embodiments of the present disclosure.

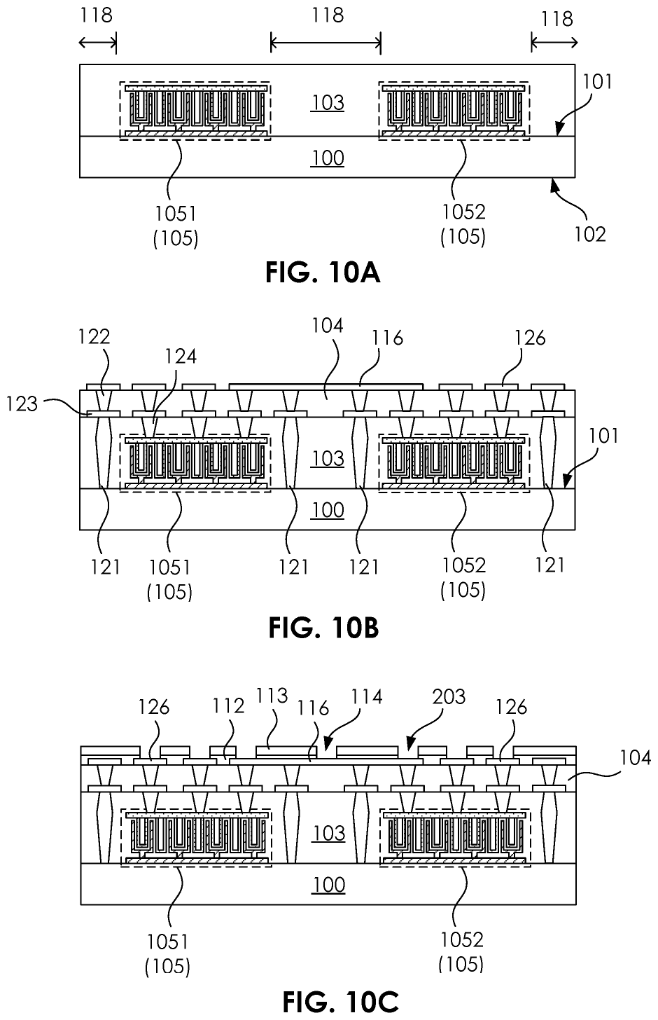

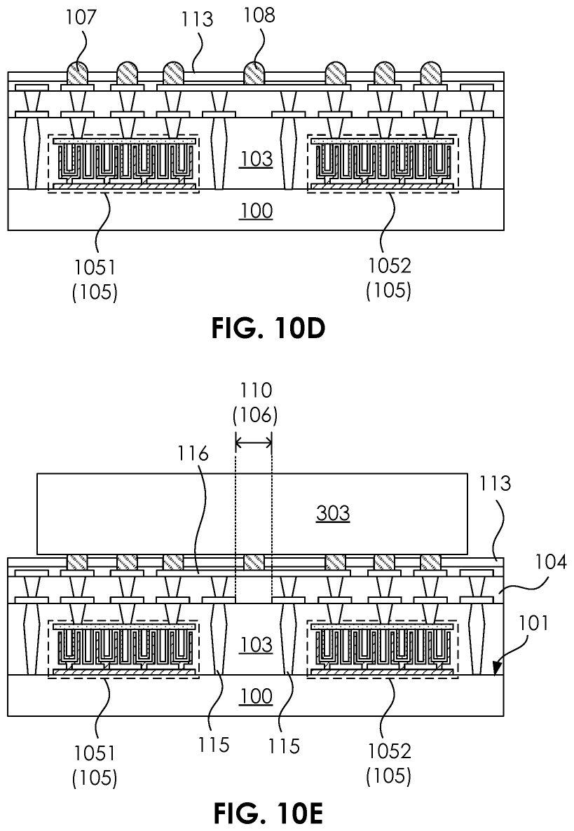

FIGS. 10A to 10E illustrate cross-sectional views of forming a semiconductor structure according to some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper”, “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first”, “second” and “third” describe various elements, components, regions, layers and/or sections, these elements, components, regions, layers and/or sections should not be limited by these terms. These terms may be only used to distinguish one element, component, region, layer, or section from another. The terms such as “first”, “second”, and “third” when used herein do not imply a sequence or order unless clearly indicated by the context.

In conventional practices, a memory die or a passive component of a memory die is often manufactured in units of a fixed size. For example, during the wafer level production, a plurality of device regions of same dimension and repeating patterns (e.g., metallization layout and/or ball map) are formed prior to dicing operations. The location of the scribe line often shows the boundary between adjacent units of device regions, and except for some test key patterns that each unit can later function normally without their presence, electrical connection of each device regions will not extend toward the region of the scribe line to avoid open circuit after the dicing operation. The fixed size unit of a memory die or a passive component of a memory die standardizes the production process yet compromises the flexibility of scaling among the plurality of units. From packaging perspective, another IC chip of die of various sizes may be bonded to the memory die or the passive component of a memory die. The bump map design of said IC chip or die is somewhat limited in order to meet the corresponding bump map of the unit of the memory die or the passive component of a memory die. On the other hand, the unit of the memory die or the passive component of a memory die with fixed size lacks the flexibility of scaling. Each unit diced from the wafer possesses the same storage capacity or the same capacitance without the possibility of double or quadruple the figures by electrically grouping a plurality of units.

In the present disclosure, a flexible bumping design of a memory die or a passive component of a memory die is disclosed. In some embodiment of the present disclosure, a bump map over the memory die or the passive component of a memory die is designed to provide a more flexible bonding arrangement in respect to another IC chip or die. The effective area of a memory die or the effective area of a passive component of a memory die populated by the conductive bumps can be easily changed in order to meet the bump map design of another IC chip or die to be bonded thereon. On the other hand, the bumping design described herein can also scale the storage capacity of the memory die or scale the capacitance of a capacitor structure.

FIG. 1 illustrates a comparative embodiment of a semiconductor structure 90 which includes a substrate 900. The substrate 900 has a first surface 901 and second surface 902 opposite to the first surface 901. An active side of the substrate 900 is in proximity to the first surface 901. A device layer 904 is formed over the first surface 901 of the substrate 900. The device layer 904 has a plurality of passive component units 906 formed therein, such as a plurality of capacitor structures. These passive component units 906 are arranged in an array in the device layer 904, while each of two adjacent passive component units 906 are spaced apart by scribe lines 908 (the scribe line can have a trench recessed from a top surface of the device layer 904 from a cross-sectional perspective, which is not shown in the FIG. 1). In the case of the individual passive component units 906 being a portion of a memory die with 128 MB storage capacity, the final packaged product including such memory die may possess 128 MB storage capacity. Alternatively stated, the layout of the passive component units 906, after dicing, somewhat limits the scalability of the storage capacity of each of the memory die.

FIG. 2 is a comparative embodiment from a top view perspective. A plurality of passive component units 906 are formed on a semiconductor wafer 91 prior to dicing, and these passive component units 906 are arranged in an array and spaced apart by the scribe lines 908. When a memory die having greater capacities, such as 256 MB, 1024 MB, etc. is desired, the structure of each of the passive component units 906 (e.g., each with 128 MB storage capacity) has to be altered, for example, physically by increasing the transistor or capacitor density, or electronically by increasing the number of bits stored in a cell, to meet such demand. However, these changes are technically fundamental, involving much research and development resources, and cannot be done by exploiting the instant layout of passive component units (e.g., each with 128 MB storage capacity).

The present disclosure provides a scalable semiconductor structure which provides flexibility in, for example, storage capacities and bump map design, by exploiting the instant device layout. A bridge portion is manufactured during wafer level production to connect adjacent passive component regions, for example, the bridge portion may electrically couple 2, 4, 6, 8 or other numbers of passive component regions based on demand. The greater the number of passive component regions being coupled, the greater effective area (i.e., the area allotted for the bump map of other IC chip(s) bonded thereto) can be obtained. With the implementation of bridge portions in the semiconductor structure, not only the storage capacity of the memory device or the capacitor structure can be scaled based on demand, but also the bump map design flexibility of the other IC chip(s) to be bonded to the memory device or the capacitor structure can be achieved.

Referring to FIG. 3A, in some embodiments, the scalable semiconductor structure 10 includes a substrate 100 having a first surface 101 and a second surface 102 opposite to the first surface 101. When the semiconductor structure 10 is a memory die, an active side of the substrate 100 is in proximity to the first surface 101. When the semiconductor structure 10 is a capacitor structure, the substrate 100 can be a metal plate without active components therein. A device layer 103 is formed over the first surface 101 of the substrate 100. A metallization structure 104 is formed over the device layer 103. In some embodiments, the substrate 100 is a semiconductor wafer that made of semiconductor materials such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations thereof, and the like, may also be used. In some embodiments, the substrate 100 is made of glass. In some embodiments, the substrate 100 is made of conductive material, such as metal.

The device layer 103 includes a plurality of passive devices 105. In some embodiments, the substrate 100 includes a front-end-of-line (FEOL) structure. The FEOL structure is the first portion of IC fabrication where the active components such as transistors are formed in the semiconductor wafer. In some embodiments, the device layer 103 includes a middle-of-line (MOL/MEOL) structure and/or a back-end-of-line (BEOL) structure. Generally, the MEOL structure is formed over the FEOL structure and prior to the formation of the BEOL structure. The definitions of what is properly considered MEOL may vary, whereas in some embodiments of the present disclosure, the MEOL structure is referred to the region that formed over the first surface 101 of the substrate 100 and below a first metal layer (M1) 104A of the metallization structure 104. In some embodiments, the dielectric material formation in the MEOL structure is referred to pre-metal dielectric (PMD) formation.

In some embodiments, the passive component units 105 embedded in the device layer 103 are passive devices such as capacitor structures. For example, the passive component units 105 having metal-insulator-metal (MIM) structures, metal-oxide-metal (MOM) structures, or the like. Generally, MIM capacitors include an insulator sandwiched between two layers of metals, while MOM capacitors are composed of numerous parallel fingers or electrodes formed on numerous metal layers.

In some embodiments, the passive component units 105 are arranged in an array and be spaced apart by a plurality of scribe lines. In other words, each of the passive component units 105 are spaced from the adjacent passive component units 105 by a scribe line region 106 which in the conventional layout serves the purpose of a scribe line. For example, the scribe line region 106 referred to herein does not necessary end up being the dicing spot due to the implementation of a bridge portion described herein. The scribe line region 106 may be immediately surrounded by the passive component units 105 or by seal ring structures 115. In some embodiments, as shown in FIG. 3B, the scribe line region 106 over a semiconductor wafer 11 includes a plurality of rows 106A and a plurality of columns 106B perpendicular to the rows 106A, and each of the passive component units 105 are enclosed by two adjacent rows 106A and two adjacent columns 106B. As previously mentioned, the scribe line region in a conventional semiconductor wafer is used to separate the passive component units from each other by sawing along the scribe line region (or simply called scribe lines). However, in some embodiment of the present disclosure, some portion of the scribe line region 106 is not necessary used to separate the passive component units 105, instead, such portion of the scribe line region 106 are remained in the final product.

Referring to FIG. 4A, FIG. 4A illustrates a portion of a semiconductor wafer in a comparative embodiment having the plurality of passive component units 105 from a top view perspective. Each of the passive component units 105 are isolated from each other by the scribe line region 106 (e.g., the rows 106A and columns 106B of a plurality of scribe lines). As illustrated in the figure, a plurality of conductive terminals 107 are formed in an area of each of the passive component units 105. In some embodiments, the plurality of conductive terminals 107 can be micro bumps, C4 bumps, solder balls, or the like. Note some of the conductive structures such as the metallization structure 104 are omitted in FIGS. 4A and 4B for the purpose of clarity in respect to delineate the bump map.

Referring to FIG. 4B. FIG. 4B illustrates a portion of a semiconductor wafer in some embodiments having the plurality of passive component units 105a-105d from a top view perspective. In some embodiments, a plurality of first type conductive terminals 108 are formed in an area of the first portion 110 of the scribe line region 106. The first portion 110 of the scribe line region 106 refers to the regions that encircled by the dashed line in FIG. 4B, or a scaled region 111 referred herein, where a number of 4 passive component units 105a-105d are grouped. A plurality of second type conductive terminals 107 are formed in an area, or a projective area, of the passive component units 105a-105d. On the other hand, a second portion 109 of the scribe line region 106 refers to the region outside the individual spliced region, where no conductive terminal is formed therein. However, in some embodiments, the second portion 109 of the scribe line region 106 may not include a conductive terminal but include a bridge portion which establishes electrical connection between adjacent scaled regions 111. The bridge portion can be implemented in any of the metallization layers, such as the first metal layer (M1) 104A as previously described in FIG. 3A.

In some embodiments of the present disclosure, these conductive terminals (i.e., the first type conductive terminals 108 and the second type conductive terminals 107) are substantially identical to each other, for example, both composed of solder material and with substantially identical dimensions. The first type conductive terminals 108 and the second type conductive terminals 107 can be categorized by their relative locations. As depicted in FIG. 7, the first type conductive terminals 108 are in an area of the first portion 110 of the scribe line region 106, and the second type conductive terminals 107 are in an area, or a projective area, of the passive component units 105a-105d. Furthermore, as shown in FIG. 4B, each of the conductive terminals are distributed within individual scaled regions 111 evenly. In other words, the first portions 110 of the scribe line region 106 is remained in the final product and the second portion 109 of the scribe line region 106 is the dicing spot during the singulation operation.

As shown in FIG. 4B, for instance, the passive component units 105a, 105b, 105c, and 105d grouped within one of the scaled regions 111 are electrically spliced into a single unit and encircled by the second portion 109 of the scribe lines region 106 at four sides. The first type conductive terminals 108 can be arranged parallel to a side of the scaled region 111 and between adjacent passive component units in the scaled region 111, which means the arrangement of the first type conductive terminals 108 in some embodiments can be designed to correspond to the positions of the passive component units therebelow, instead of randomly distributing the first type conductive terminals 108 over the metallization structure. Multiple passive component units, such as the passive component units 105a-105d shown in FIG. 4B, can be integrated into a single spliced semiconductor structure having a storage capacity or a capacitor capacity about four times to a single passive component unit. For example, in the circumstances that each of the passive component units 105a-105d is a memory structure (e.g., memory die) having a storage capacity of 128 MB, the spliced semiconductor structure including the spliced passive component units 105a-105d can have a storage capacity of 512 MB. In other circumstances, the spliced semiconductor structure including two or more of the passive component units can have a storage capacity of 256 MB, 768 MB, 1024 MB, etc., depending on the number of the passive component units included.

The number of the passive component units included in a spliced semiconductor structure, or the scaled region as previously mentioned, is customizable. For example, based on the demand of a particular storage capacity or a particular size of effective area, the passive component units 105 and the first type conductive terminals 108 can be formed on the semiconductor wafer during the wafer level production, and later being packaged with other IC chips or dies, and diced along the second portion 109 of the scribe line region 106. On the other hand, the number of the scaled regions 111 per semiconductor package is customizable based on the required storage capacity. For example, as previously discussed, in the embodiments that the second portion 109 of the scribe line region 106 includes the bridge portion 116, which allows adjacent scaled regions 111 to be electrically connected, one can divide the wafer of FIG. 4B based on the specified storage capacity and obtain 2, 4, or 6 scaled regions 111 in one semiconductor device package after the dicing operation.

Still referring to FIG. 4B, once the first type conductive terminals 108 are formed to meet particular packaging requirements, the first portion 110 of the scribe line region 106 that having the first type conductive terminals 108 would be remained in the final product. Compared to the second portion 109 of the scribe line region 106, the morphology of the first portion 110 of the scribe line region 106 is different thereto and will be described in FIG. 5A and FIG. 5B.

Referring to FIG. 5A, FIG. 5A is a cross-sectional view of the semiconductor structure along line A in FIG. 4B. In some embodiments, the scribe line region 106 surrounds the plurality of passive component units 105. In some embodiments, the scribe line region 106 is located between two adjacent passive component units 105, or when cross-referencing to FIG. 4B, the scribe line region 106 is located between two adjacent scaled regions 111 (e.g., between a first scaled region and a second scaled region adjacent to the first scaled region; for the purpose of understanding, the passive component units grouped within the first scaled region and the second scaled region can be distinguished into the first passive component units and the second passive component units, respectively). In some embodiments, the second portion 109 of the scribe line region 106 includes a first trench 201 having a first depth D1. In some embodiments, the first depth D1 is in a range of from about 10 μm to about 15 μm. In some embodiments, the first depth D1 is in a range of from about 5 μm to about 10 μm. In some embodiments, a bottom of the first trench 201 is levelled with the metallization structure 104. In some embodiments, a side of a passivation layer 112 over the metallization structure 104 is exposed at a sidewall of the first trench 201. In some embodiments, a side of a polymeric layer 113 over the passivation layer 112 is exposed at the first trench 201. In some embodiments, the polymeric layer includes a polyimide (PI) layer. The scribe line region 106 depicted in FIG. 5A is the dicing spot and shall not remain the final product, and hence the second portion 109 of the scribe line region 106 is free of the first type conductive terminal 108 and the second type conductive terminal 107.

Referring to FIG. 5B, FIG. 5B is a cross-sectional view of the semiconductor structure along line B in FIG. 4B. In some embodiments, the scribe line region 106 is located between two adjacent passive component units 105, or when cross-referencing to FIG. 4B, the scribe line region 106 is located within one of the scaled regions 111. The scribe line region 106 in FIG. 5B is the first portion 110 of the scribe line region 106, which will be remained in the final product. In some embodiments, the first portion 110 of the scribe line region 106 includes a plurality of second trenches 114 that, each of them having a second depth D2. In some embodiments, the second depth D2 is in a range of from about 5 μm to about 10 μm. In some embodiments, the second depth D2 is no greater than about 5 μm. In some embodiments, the second depth D2 is less than the first depth D1. In some embodiments, a bottom of the second trench 114 exposes a top metal layer of the metallization structure 104. In some embodiments, a side of the passivation layer 112 over the metallization structure 104 is exposed at a sidewall of the second trench 114. In some embodiments, a side of the polymeric layer 113 over the passivation layer 112 is exposed at the second trench 114. The second trenches 114 are formed to provide an opening for conductive bumps (e.g., the second conductive terminals) to contact with the top metal layer of the metallization structure 104, or any conductive pad electrically coupled to the metallization structure 104. Accordingly, each of the second trenches 114 is much shallower than that of the first trench 201.

By building a bridge portion traversing the first portion 110 of the scribe line region 106, the conductive terminals (e.g., the first type conductive terminals 108) can be distributed over the region that conventionally used as scribe lines, so that the passive component units 105 adjacent to the first portion 110 of the scribe line region 106 can be electrically spliced. By splicing the passive component units 105, the effective area (i.e., the area populated by contact bumps) of the semiconductor die over these passive component units 105 can be increased, and thereby the IC chip(s) or die(s) to be bonded to the semiconductor structure of the present disclosure can have better arrangement flexibility.

In a comparative embodiment, referring to FIG. 6A, which illustrates a semiconductor wafer having a first die area 801 and a second die area 802 adjacent to the first die area 801. Each of the first die area 801 and a second die area 802 can have one or more passive component units formed in a device layer over the semiconductor wafer. Generally, each of the bump areas 811 or 812 (or so-called effective area) is smaller than the die area 801 or 802. For example, as shown in FIG. 6A, a first bump area 811 (illustrated by bold dashed line) is within the first die area 801, and a second bump area 812 (illustrated by bold dashed line) is within the second die area 802. Each of the first bump area 811 and the second bump area 812 has an area of 530 μm*230 μm, while each of the first die area 801 and the second die area 802 has an area of 600 μm*300 μm. That is, in the example shown in FIG. 6A, the area of each bump area is 121,900 μm², while the area of each die area is 180,000 μm², and the effective bump area (bump area/die area) is about 67.7%.

In some embodiments of the present disclosure, the first die area 801 and the second die area 802 are identical to those in the comparative embodiment shown in FIG. 6A. However, as previously mentioned, because the passive component units 105 adjacent to the first portion 110 of the scribe line region 106 can be electrically spliced though the bridge portion and the conductive terminals (e.g., the first type conductive terminals 108 previously shown in FIG. 4B) over/within the first portion 110 of the scribe line region 106, and therefore, there are greater areas can be counted as the effective area populated by the conductive bumps. For instance, as shown in FIG. 6B, which illustrates the semiconductor wafer 11 having a first die area 401 and a second die area 402 adjacent to the first die area 401. The first die area 401 and the second die area 402 can be substantially identical to the first die area 801 and the second die area 802 previously shown in FIG. 6A. Compared with the comparative embodiment shown in FIG. 6A, a spliced bump area 413 in FIG. 6B can have an area greater than a summation of the first bump area 811 and the second bump area 812 in FIG. 6A. When a width W1 of the first portion 110 of the scribe line region 106 is about 80 μm, the spliced bump area 413 can have an area of 530 μm*610 μm, while the splice of the first die area 401 and the second die area 402 can have an area of 600 μm*680 μm. Accordingly, in the example shown in FIG. 6B, the area of the spliced bump area 413 is 323,300 μm², while the area of the die area is 408,000 μm², and the effective area is about 79.2%. Therefore, the splicing of the die areas not only produces a greater storage capacity of the passive component units, but also expand the effective area which populated by the conductive bumps, allowing more arrangements of the other IC chip or IC die to be bonded thereto.

Referring to FIG. 7, in some embodiments, the semiconductor structure further includes a seal ring structure 115 surrounds the peripheral of the passive component units 105. The seal ring structure 115 is configured to protect the die area (e.g., the first die area 401 and the second die area 402 previously shown in FIG. 6B) from static shock and prevent crack propagation or edge delamination during singulation procedures, thus eliminating chip package interaction (CPI) reliability issues. As shown in FIG. 7, each of the passive component units 105 are laterally surrounded by the seal ring structure 115 that extends from the first surface 101 of the substrate 100 to the metallization structure 104. The metallization structure 104 further includes a bridge portion 116 electrically connecting two adjacent passive component units 105. The bridge portion 116 can be any conductive structure located in or near the first portion 110 of the scribe line region 106 that electrically connect the passive component units 105 at opposite sides. Referring back to FIG. 3A, the bridge portion 116 can refer to the conductive lines or vias (not shown) in or near the scribe line region 106. Referring to FIG. 7, the bridge portion 116 can refer to the conductive lines or vias (not shown) in or near the first portion 110 of the scribe line region 106. In FIG. 7, the first type conductive terminals 108 are disposed projectively over the conductive bridge portion 116 of the metallization structure 104. The term “projectively” in the present disclosure refers to the spatial relation that an item is directly over or below another item from a cross sectional perspective. The directly over or below encompasses the circumstances of completely overlap or partially overlap, as long as each of the two items has respectively a portion being vertically overlapped. Via the bridge portion 116, the first type of conductive terminal 108 can electrically connect to the second type conductive terminal 107. The seal ring structure 115 is at least partially under a vertical projection of the bridge portion 116 of the metallization structure 104.

In some alternative embodiments, to gain further de-scaling flexibility, the first portion 110 of the scribe line region 106 may become the dicing spot during singulation operations. The seal ring structure 115 can be formed in each of the first portion 110 and second portion 109 of the scribe line region 106, and when a fewer number of the passive component units 105 in a scaled region 111 (as previously depicted in FIG. 4B) is required based on demand, one receiving the semiconductor wafer can dice alone the scribe line region 106 proximal to the seal ring structure 115 and populated with first type conductive terminals 108.

Still referring to FIG. 7, in some embodiments, the seal ring structures 115 are disposed near the scribe line region 106, and the conductive bridge portion 116 is electrically connected to the two adjacent passive component units 105 by crossing the scribe line region 106. In some embodiments, the metallization structure 104 includes one or more metal layers. In some embodiments, each of the plurality of passive component units 105 are laterally spaced from each other in the device layer 103 by the seal ring structures 115 and the scribe line region 106 between the seal ring structures 115. In some embodiments, each of the second type conductive terminal 107 is at a same level as the first type conductive terminals 108. In some embodiments, a height of the seal ring structure 115 is greater than a height of the passive component units 105).

Referring to FIG. 7 and FIG. 8, FIG. 8 illustrates a polymeric layer 113 over the metallization structure 104. In some embodiments, the plurality of conductive terminals (e.g., the first type and the second type conductive terminals 108, 107) are protruding from the polymeric layer 113 and laterally in contact with the polymeric layer 113. In some embodiments, the polymeric layer 113 is configured to improve the mechanical strength of the conductive terminals and the mechanical strength of the semiconductor structure. The polymeric layer 113 can also prevent particles from directly impact the memory structure underneath. For instance, compared to other dielectric materials such as silicon oxide (SiO₂), polymeric layer 113 (e.g., polyimide) demonstrates more robust physical properties and stronger chemical bond. Particularly, the polymeric layer 113 can have a tensile strength up to about 230 MPa and a compressive strength up to about 4 GPa, whereas the silicon oxide only have a tensile strength up to about 155 MPa and a compressive strength up to about 1.6 GPa. In some embodiments, the thickness of the polymeric layer 113 is about 10 μm. The thickness of the first type conductive terminal (not shown in FIG. 8) or the thickness of the second type conductive terminal 107 is greater than the thickness of the polyimide layer 113. Furthermore, in the scenario that the passive component units 105 in the device layer 103 are a portion of a memory die, the polymeric layer 113 can be used to projectively cover the passive component units 105 which are sensitive to space radiation such as alpha particles.

FIGS. 9A to 9E show the formation of the second portion 109 of the scribe lines region 106. Manufacturing operations adopted to form the conductive bridge portion 116 crossing the first portion 110 of the scribe line region 106 to electrically splice the adjacent passive component units 105 are described in FIGS. 10A to 10E.

Referring to FIG. 9A, in some embodiments, the substrate 100 having the first surface 101 is provided. In some embodiments, the device layer 103 can be formed over the first surface 101 of the substrate 100, wherein the device layer 103 includes a plurality of passive component units 105 (e.g., a first passive component unit 1051 and a second passive component unit 1052). Each of the passive component units 105 is distanced from an adjacent passive component by a predetermined space 118 in the device layer 103. In some embodiments, the predetermined space 118 is reserved for the seal ring structures and/or the scribe line regions.

Referring to FIG. 9B, the seal ring structures can be formed partly by a plurality of first through vias 121 extending through the device layer 103 in the predetermined region 118 (see FIG. 9A) and surrounding all sides of the passive component units 105. In some embodiments, the height of each of the first through vias 121 is greater than the thickness or the height of the passive component units 105. In some embodiments, one or more metal layers (e.g., metal layer 123 and metal layer 126) and one or more second through vias 122 can be formed over the first through vias 121 and constituting another portion of the seal ring structure. In some embodiments, the number of the metal layers 123, 126 can be two or three. For example, two metal layers can be implemented in a capacitor structures, and three metal layers can be implemented in a memory structure.

In some embodiments, a top end of the first through vias 121 is levelled with a top end of the third vias 124. The third vias 124 is in contact with a top electrode of the passive component units 105. Although not illustrated in FIG. 9B to FIG. 9E, vias having a structure similar to the first through vias 121 may be positioned between the seal ring structure and the passive component units 105 and is in contact with a bottom electrode of the passive component units 105. The seal ring structure, on the other hand, is electrically isolated from the passive component units 105. In some embodiments, the third vias 124 and the first through vias 121 can be formed concurrently in a signal operation, for example, trench formation in the dielectric portion of the device layer 103, electroplating the first through vias 121 and the third vias 124, and the planarization operations, etc.

As shown in FIGS. 9B and 9C, in some embodiments, after forming the metallization structure 104 over the device layer 103, and further forming the passivation layer 112 and the polymeric layer 113 subsequently over the metallization structure 104, a plurality of openings 203 can be formed at the passivation layer 112 and the polyimide layer 113 to expose the metal layer 126. In some embodiments, the metal layer 126 exposed to the openings 203 may serve as a conductive pad to receive conductive bumps transmitting signals through the top electrode of the passive component 105. Although not illustrated in FIG. 9C, some openings 203 may be formed over via structures electrically connected to the bottom electrode of the passive component 105. The scribe line region 106 includes a trench 201 recessed from a top surface of a dielectric layer of the metallization structure 104 to facilitate subsequent dicing operations.

Still referring to FIG. 9D, in some embodiments, the second type conductive terminals 107 can be formed in the openings 203. Each of the second type conductive terminals 107 are protruding from the polymeric layer 113 and laterally in contact with the polymeric layer 113. Because the region between the first passive component 1051 and the second passive component 1052 includes a scribe line, no conductive terminals are formed within the scribe line region 106. Referring to FIG. 9E, a plurality of semiconductor devices can be mounted over the passive component units 105 through bumping operations. For instance, a first semiconductor device 301 and a second semiconductor device 302 can be bonded to the first passive component 1051 and the second passive component 1052, respectively. Because no conductive terminal (or the first type conductive terminals 107 referred herein) is populated in the scribe line region 106, the bump pad arrangement of the first semiconductor device 301 and the second semiconductor device 302 can only align with the bumps in the region populated with the second type conductive terminals 107.

Referring to FIGS. 10A and 10B, formation of the passive component units 105, the first through vias 121, the second vias 122, the third vias 124, and the metal layers 123, 126, are substantially identical to those described in FIG. 9A to FIG. 9E. In FIG. 10B, when forming the second metal layer 126 over the first passive component 1051 and the second passive component 1052, a bridge portion 116 overlapping the scribe line region 106 is concurrently formed. The bridge portion 116 may extend across the vias structures in connection to the top electrode and the bottom electrode of the passive component units 105, and in some embodiments, extend across the seal ring structure, in order to provide electrical connection between the first passive component 1051 and the second passive component 1052.

Next, referring to FIG. 10C, the passivation layer 112 and the polymeric layer 113 can subsequently form over the metallization structure 104, and a plurality of openings 203 can be formed in the passivation layer 112 and the polymeric layer 113 to expose the metal layer 126. Similar to previously described, the metal layer 126 exposed to the openings 203 may serve as a conductive pad to receive conductive bumps transmitting signals through the top electrode of the passive component 105. Although not illustrated in FIG. 10C, some openings 203 may be formed over via structures electrically connected to the bottom electrode of the passive component 105. One of the openings 114 projectively over the scribe line region 106 exposes the conductive bridge portions 116 at the level of the metal layer 126. In some embodiments, the opening 114 shares a same depth and dimensions as other opening 203. Alternatively stated, the opening 114 exposes the conductive bridge portion 116 and does not go further down to the dielectric layer of the metallization structure 104, as the trench 201 previously described in FIG. 9C.

Referring to FIG. 10D, in some embodiments, the second type conductive terminals 107 can be formed in the openings 203 and the first type conductive terminal(s) 108 can be formed in the opening 114. Each of the conductive terminals (i.e., the second type conductive terminals 107 and the first type conductive terminals 108) are protruding from the polyimide layer 113 and laterally in contact with the polyimide layer 113. The scribe line region 106 illustrated in this embodiment will not be the dicing spot and thus will remain in the final product. Referring to FIG. 10E, a semiconductor device can be mounted over the passive component units through bumping operations. For instance, a third semiconductor device 303 can be mounted over the first passive component 1051, the second passive component 1052 and the scribe line region 106 therebetween. That is, the effective area of bump array is enlarged, and the bump pad arrangement of the third semiconductor device 303 can align with the bumps in the region populated with both the first type conductive terminals 108 and the second type conductive terminals 107. Although not illustrated in FIG. 10E, two or more semiconductor devices can be mounted over the effective area defined by the first passive component 1051 and the second passive component 1052 spliced together, as long as the bump arrangement of said two or more semiconductor devices matches the flexible bump map provided by the spliced passive component units, or the scaled region 111, as previously discussed in FIG. 4B.

According to the embodiments of the present disclosure, different passive component units can be connected through the conductive bridge structures that crossing the region that conventionally used as scribe lines, while whether the conductive bridge structures to cross such region to splice the adjacent passive component units is scalable, depend on the requirement of the buyer of the semiconductor wafer having those passive component units formed thereon. By using such scalable semiconductor structure, the ball map over the passive component units can be improved to provide a more flexible mounting allowance of the semiconductor devices mounted thereover. In other aspect, the electrical connections between the semiconductor device and the passive component units can also be improved, for example, there can be more conductive terminals between the semiconductor device and the passive component units, and thus the bandwidth can be increased.

In one exemplary aspect, a semiconductor structure is provided. The semiconductor structure includes a substrate, a device layer, and a metallization structure. The substrate has a first surface. The device layer is over the first surface of the substrate. The device layer includes a plurality of passive component units. The metallization structure is over the device layer. The metallization structure includes a conductive bridge portion electrically connecting two adjacent passive component units.

In another exemplary aspect, a semiconductor structure is provided. The semiconductor structure includes a semiconductor wafer, a plurality of first passive component units, a first type conductive terminal, and a second type conductive terminal. The plurality of passive component units are grouped into a first scaled region on the semiconductor wafer from a top view perspective. The first type conductive terminal is over the first scaled region and free from overlapping with the plurality of passive component units. The second type conductive terminal is over the first scaled region and overlapping with the plurality of passive component units.

In yet another exemplary aspect, a semiconductor structure is provided. The semiconductor structure includes a substrate, a passive device layer, a metallization structure, a first type conductive terminal, and a polymeric layer. The substrate has a first surface. The passive device layer is over the first surface of the substrate, the passive device layer includes two discrete passive component units. The metallization structure is over the passive device layer. The two passive component units in the passive device layer are electrically connected through a bridge portion of the metallization structure. The first type conductive terminal is disposed projectively over the bridge portion of the metallization structure. The polymeric layer is over the metallization structure, configured to laterally surround the first type conductive terminal.

The foregoing outlines structures of several embodiments so that those skilled in the art may better understand the aspects of the present disclosure. Those skilled in the art should appreciate that they may readily use the present disclosure as a basis for designing or modifying other operations and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate having a first surface;
a device layer over the first surface of the substrate, the device layer comprising a plurality of passive component units; and
a metallization structure over the device layer, the metallization structure comprising a conductive bridge portion electrically connecting two adjacent passive component units.

2. The semiconductor structure of claim 1, further comprising a first type conductive terminal disposed projectively over the conductive bridge portion of the metallization structure.

3. The semiconductor structure of claim 2, further comprising a second type conductive terminal disposed projectively over one of the plurality of passive component units, wherein the second type conductive terminal is at a same level to the first type conductive terminal.

4. The semiconductor structure of claim 3, wherein the conductive bridge portion comprises a horizontal metal line extending across the two adjacent passive component units.

5. The semiconductor structure of claim 2, wherein one of the plurality of passive component units comprises a silicon capacitor structure.

6. The semiconductor structure of claim 2, further comprising a seal ring structure in the device layer between two adjacent passive component units, wherein the seal ring structure is at least partially under a vertical projection of the conductive bridge portion of the metallization structure.

7. The semiconductor structure of claim 6, wherein a height of the seal ring structure is greater than a height of one of the passive component units.

8. The semiconductor structure of claim 1, further comprising a scribe line region surrounding the plurality of passive component units, wherein the scribe line region includes a recessed trench in a dielectric layer of the metallization structure.

9. The semiconductor structure of claim 1, wherein the metallization structure comprises two metal layers.

10. The semiconductor structure of claim 2, further comprising a polyimide layer over the metallization structure, the first type conductive terminal protruding from and laterally in contact with the polyimide layer.

11. A semiconductor structure, comprising:
a semiconductor wafer;
a plurality of first passive component units grouped into a first scaled region on the semiconductor wafer from a top view perspective;
a first type conductive terminal over the first scaled region and free from overlapping with the plurality of first passive component units; and
a second type conductive terminal over the first scaled region and overlapping with the plurality of first passive component units.

12. The semiconductor structure of claim 11, further comprising:
a plurality of second passive component units grouped into a second scaled region; and
a scribe line region formed between the first scaled region and the second scaled region.

13. The semiconductor structure of claim 12, wherein the scribe line region is free of the first type conductive terminal and the second type conductive terminal.

14. The semiconductor structure of claim 11, wherein the first scaled region comprises any even number of first passive component units.

15. The semiconductor structure of claim 11, wherein the first type of conductive terminal is electrically connected to the second type conductive terminal.

16. The semiconductor structure of claim 11, further comprising a plurality of first type conductive terminals arranged parallel to a side of the first scaled region and between adjacent first passive component units.

17. A semiconductor structure, comprising:
a substrate having a first surface;
a passive device layer over the first surface of the substrate, the passive device layer comprising two discrete passive component units;
a metallization structure over the passive device layer, the two passive component units in the passive device layer electrically connected through a bridge portion of the metallization structure;
a first type conductive terminal disposed projectively over the bridge portion of the metallization structure; and
a polymeric layer over the metallization structure, configured to laterally surround the first type conductive terminal.

18. The semiconductor structure of claim 17, further comprising a second type conductive terminal disposed projectively over the passive component units and laterally surrounded by the polymeric layer, wherein the second type conductive terminal is leveled with the first type conductive terminal.

19. The semiconductor structure of claim 18, wherein the first type conductive terminal and the second type conductive terminal each having a thickness greater than a thickness of the polymeric layer.

20. The semiconductor structure of claim 17, wherein the polymeric layer comprises a polyimide layer.

21. The semiconductor structure of claim 17, wherein the polymeric layer projectively covers the passive component units in the passive device layer.
